(19) United States
(12) Patent Application Publication
(10) Pub. No.: US 2011/0012691 A1
(43) Pub. Date: Jan. 20, 2011

(54) 1:9 BROADBAND TRANSMISSION LINE TRANSFORMER

(76) Inventor: Michael J. Schoessow, Belmont, CA (US)

Correspondence Address: Agilent Technologies, Inc. in care of:;CPA Global, P. O. Box 52050, Minneapolis, MN, 55402, US

(21) Appl. No.: 12/503,752

(22) Filed: Jul. 15, 2009

(51) Int. Cl. H03H 7/00; H03H 7/42

(52) U.S. Cl. 333/26; 333/24 R

(57) ABSTRACT

A single-core transmission line transformer includes first, second and third transmission lines, and first and second ports. The first and second transmission lines are wound around a common core. The first port interconnects respective first ends of the first and second transmission lines in parallel. The second port communicates with respective second ends of the first and second transmission lines. The third transmission line communicates with the first and second transmission lines without being wound around any solid core. The impedance transformation ratio of the transformer is 1:9 in a direction from the first port to the second port.

### FIELD OF THE INVENTION

The present invention relates generally to transmission line transformers. More particularly, the present invention relates to 1:9 transmission line transformers utilizing a common magnetic core.

### BACKGROUND OF THE INVENTION

A transmission line transformer transmits electromagnetic energy by way of the traverse electromagnetic (TEM) mode, or transmission line mode, instead of by way of the coupling of magnetic flux as in the case of a conventional transformer. The design and theory of various transmission line transformers are described in Sevick, J., “Transmission Line Transformers,” 4^{th} ed., Noble Publishing Corp., 2001.

FIG. 1 is a schematic illustration of a Guanella-type 1:1 transmission line transformer 100, often referred to as the “basic building block” of many broadband transmission line transformers. The 1:1 transmission line transformer 100 generally includes a single transmission line 110 in signal communication with a two-terminal input port (PORT 1) 112 and a two-terminal output port (PORT 2) 114. The transmission line 110 includes a first electrical conductor 122 and a second electrical conductor 124 wound or coiled around a magnetic core 126. The magnetic core 126 is typically constructed of a solid material such as ferrite or powdered iron. The first and second conductors 122 and 124 may be characterized as having respective input ends at the side of the input port 112 and respective output ends at the side of the output port 114. The transmission line 110 has a physical length generally taken to be the distance from the input ends to the output ends when the structure of the transmission line 110 (comprising its first and second conductors 122 and 124) is straightened out. The direction of the transmission of electromagnetic energy from the input port 112 to the output port 114 is often characterized as being the longitudinal direction.

The transmission line transformer 100 illustrated in FIG. 1 provides an impedance transformation ratio of 1:1. That is, the output voltage and current replicate the input voltage and current. The usefulness of this type of transformer derives from the fact that the common-mode input and output potentials can differ from each other. In other words, the transmission line transformer 100 can support a longitudinal voltage drop between its input port 112 and output port 114. Although a conventional transformer also accomplishes this, the advantage of the transmission line transformer 100 is that its loss and bandwidth are greatly superior to those of a conventional transformer. These advantages are largely related to the properties of the transmission line 110 rather than the properties of the magnetic core 126.

In practice, a transmission line transformer such as shown in FIG. 1 may be constructed by winding a length of transmission line onto a ferrite or powdered iron core, or by stringing cores onto the transmission line like beads. Typical configurations of an actual transmission line include coaxial cable, twisted-pair wires, twin-lead ribbon cable, strip line, and microstrip, all of which are known to persons skilled in the art.

In 1944, Guanella showed how groups of 1:1 transmission line transformers could be configured to provide any impedance transformation ratio N², where N is the quantity of 1:1 transmission line transformers (i.e., basic building blocks) employed. See Guanella, G., “New Method of Impedance Matching in Radio-Frequency Circuits,” Brown Boveri Review, September 1944, pp. 327-329. For instance, two 1:1 transmission line transformers can be utilized to create a 1:4 transformer, three 1:1 transmission line transformers can be utilized to create a 1:9 transformer, and so on. This is accomplished by connecting the inputs of the individual transmission lines in parallel and connecting their outputs in series. When the transmission lines are all of the same length, the voltages on the output side will all add in-phase in a frequency-invariant manner and the performance bandwidth will be very wide.

As an example, FIG. 2 illustrates a balanced, two-core 1:4 transmission line transformer 200. The 1:4 transmission line transformer 200 consists of two individual transmission lines 210 and 230 located between an input port 212 and an output port 214. The two individual transmission lines 210 and 230 are respectively wound about physically separate and distinct magnetic cores 226 and 246. The inputs of the two individual transmission lines 210 and 230 are connected in parallel and their outputs are connected in series. As a result of this circuit configuration, if the voltage across the input port 212 is taken to be Vₛ, the voltage across the output port 214 will be 2Vₛ, corresponding to a voltage transformation ratio of 2. The current transformation ratio for this circuit is 1/2, and thus the resulting impedance transformation ratio is 1:4.

As another example, FIG. 3 illustrates a balanced, three-core 1:9 transmission line transformer 300, including the various voltages and currents associated with this circuit. The node voltages are all with respect to ground and in this case the circuit is assumed to be balanced about ground. The 1:9 transmission line transformer 300 consists of three individual transmission lines 310, 330 and 350 located between an input port 312 and an output port 314. The three individual transmission lines 310, 330 and 350 are respectively wound about physically separate and distinct magnetic cores 326, 346 and 366. The inputs of the three individual transmission lines 310, 330 and 350 are connected in parallel and their outputs are connected in series. As a result of this circuit configuration, if the voltage across the input port 312 is taken to be Vₛ, the voltage across the output port 314 will be 3Vₛ, corresponding to a voltage transformation ratio of 3. The current transformation ratio for this circuit is 1/3, and thus the resulting impedance transformation ratio is 1:9.

The 1:4 transmission line transformer 200 illustrated in FIG. 2 may be modified by winding the two transmission lines 210 and 230 onto a common magnetic core. This modification is possible because the longitudinal voltage drop magnitudes across the respective two transmission lines 210 and 230 are identical. In such a modification, the two transmission lines 210 and 230 are wound onto the magnetic core in opposite directions such that they will aid each other via their mutual inductance. Because the coupling between the two transmission lines 210 and 230 increases the total magnetizing inductance, the low-frequency cutoff is extended compared to the case in which two separate cores 226 and 246 are employed, thereby providing an advantage over the two-core implementation specifically illustrated in FIG. 2. On the other hand, regarding the 1:9 transmission line transformer 300 illustrated in FIG. 3, winding all three transmission lines 310, 330 and 350 onto a common core is not workable because the three transmission lines 310, 330 and 350 do not have identical longitudinal voltage drops and would thus interfere with each other. Illustrations of 1:9 transmission line transformers in the literature always show three separate cores, consistent with the circuit illustrated in FIG. 3.

There continues to be a need for utilizing 1:9 transmission line transformers in various types of electronic circuitry, particularly where broadband transmission of energy is desirable, including in various applications entailing radio-frequency (RF) signal processing and communications. There continues to be a need for reducing the physical size and cost of the components utilized in electronic circuitry. Specifically in the case of transmission line transformers, there is a need for configurations able to utilize transmission lines of shorter physical length so as to yield advantages in transmission efficiency (e.g., less signal loss through the circuit). Accordingly, there is a need for providing improved 1:9 transmission line transformers that address the foregoing problems.

### SUMMARY OF THE INVENTION

To address the foregoing problems, in whole or in part, and/or other problems that may have been observed by persons skilled in the art, the present disclosure provides methods, processes, systems, apparatus, instruments, and/or devices, as described by way of example in implementations set forth below.

According to one implementation, a single-core transmission line transformer includes first, second and third transmission lines, and first and second ports. The first transmission line is wound around a solid core of magnetic material. The second transmission line is wound around the solid core. The first port interconnects respective first ends of the first transmission line and the second transmission line in parallel. The second port communicates with respective second ends of the first transmission line and the second transmission line. The third transmission line communicates with the first transmission line and the second transmission line without being wound around any solid core. The third transmission line includes a first side communicating with the respective first ends of the first transmission line and the second transmission line, and a second side communicating with the respective second ends of the first transmission line and the second transmission line. The impedance transformation ratio of the single-core transmission line transformer is 1:9 in a direction from the first port to the second port.

In some implementations, the first port is an input port and the second port is an output port of the single-core transmission line transformer. In other implementations, the first port is the output port and the second port is the input port.

According to another implementation, a method is provided for forming a single-core transmission line transformer. A first transmission line is wound around a solid core of magnetic material. A second transmission line is wound around the solid core. A first port is formed by interconnecting respective first ends of the first transmission line and the second transmission line in parallel. A second port is formed by placing respective second ends of the first transmission line and the second transmission line in communication with respective nodes of the second port. A third transmission line is placed in communication with the first transmission line and the second transmission line without being wound around any solid core. The third transmission line includes a first side communicating with the respective first ends of the first transmission line and the second transmission line, and a second side communicating with the respective second ends of the first transmission line and the second transmission line. The impedance transformation ratio of the single-core transmission line transformer is 1:9 in a direction from the first port to the second port.

Other devices, apparatus, systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The invention can be better understood by referring to the following figures. The components in the figures are not necessarily to scale, emphasis instead being placed upon illustrating the principles of the invention. In the figures, like reference numerals designate corresponding parts throughout the different views.

FIG. 1 is a schematic view of a 1:1 transmission line transformer of known configuration.

FIG. 2 is a schematic view of a 1:4 transmission line transformer of known configuration.

FIG. 3 is a schematic view of a 1:9 transmission line transformer of known configuration.

FIG. 4 is a schematic view of an example of a 1:9 transmission line transformer provided in accordance with the present teachings.

FIG. 5 is a top plan view of one example of a physical implementation of a 1:9 transmission line transformer in accordance with the present teachings.

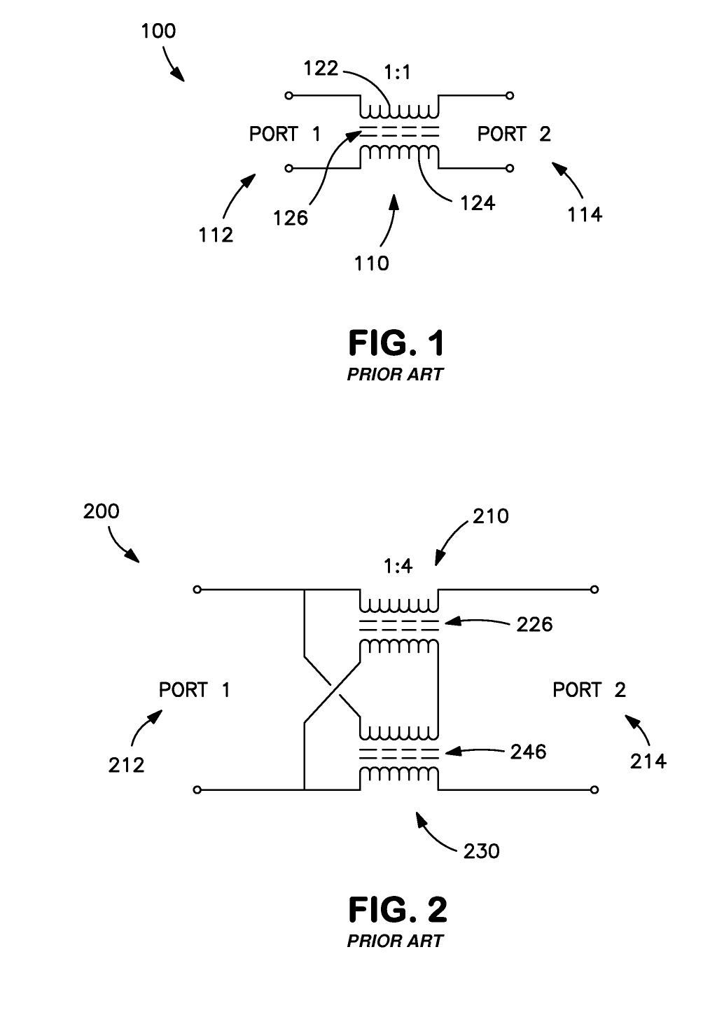

### DETAILED DESCRIPTION OF THE INVENTION

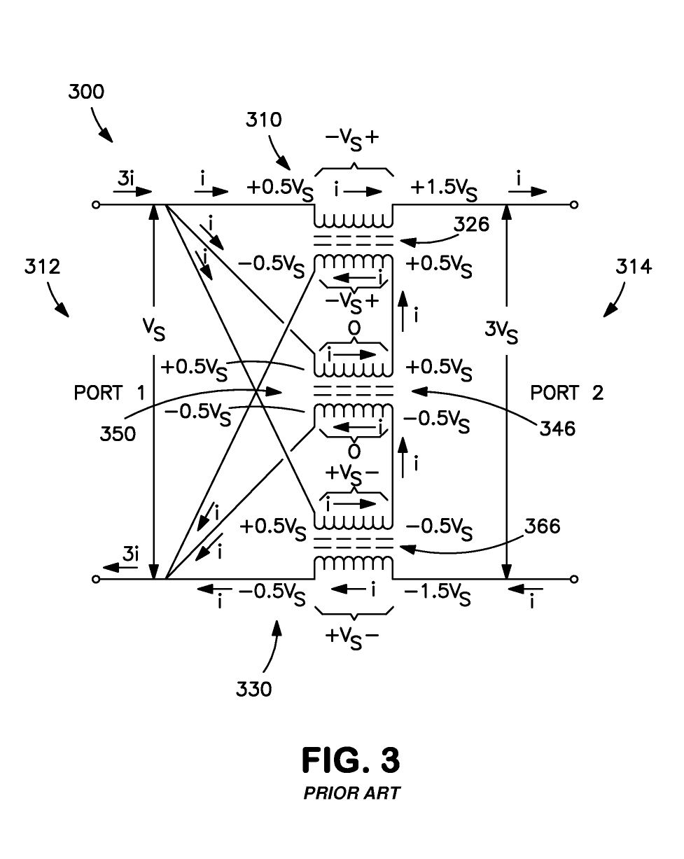

The subject matter disclosed herein is based in part on the following observations. Referring back to FIG. 3, the two outer transmission lines 310 and 330 each support a longitudinal voltage drop of Vₛ. The center transmission line 350, however, has no longitudinal voltage drop. Consequently, the center transmission line 350 does not need any longitudinal, or common-mode, impedance from input to output and therefore does not need a magnetic core. The only purpose of the magnetic core is to provide a significant broadband longitudinal impedance along the transmission line. Thus, it is proposed herein that if a particular transmission line does not require any longitudinal impedance then that transmission line does not require a core. Because the two outer transmission lines 310 and 330 have voltage drops of identical magnitude but opposite polarity they can now be wound onto a common core, provided they are wound in opposite directions and the center transmission line 350 is not also wound onto that common core.

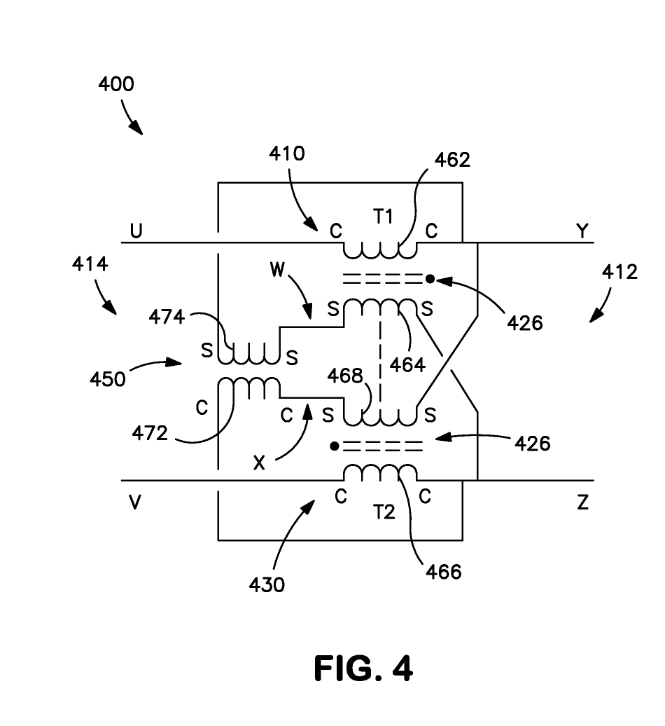

FIG. 4 is a schematic view of an example of a single-core 1:9 transmission line transformer 400 provided in accordance with the present teachings. From the perspective of FIG. 4, the low-impedance (input) side is on the right and the high-impedance (output) side is on the left. The single-core transformer 400 includes a first transmission line 410, a second transmission line 430, and a third transmission line 450. The first transmission line 410 is wound around a solid magnetic core 426—that is, a core constructed of a solid magnetic material. As non-limiting examples, the solid magnetic core 426 may be constructed of ferrite, powdered iron, wound or stacked metal ribbon, strips, or metals configured as any other shapes suitable for a given application. The second transmission line 430 is wound around the same solid magnetic core 426. That is, the first transmission line 410 and the second transmission line 430 are wound around a single or common magnetic core 426. The third transmission line 450 may be thought of as being wound around a gas (e.g., air) core, but in any case is not wound around a solid core. As a result, the single-core transformer 400 may be considered as including three distinct 1:1 transmission line transformers T1, T2 and T3. The inputs to transformers T1 and T2 are connected in parallel. The transformer T3 is interconnected to the transformers T1 and T2 in a manner that results in a transformation ratio of 1:9.

The single-core transformer 400 includes an input port 412 and an output port 414. In the schematic illustration of FIG. 4, nodes Y and Z are associated with the input port 412 and nodes U and V are associated with the output port 414. Node W represents an electrical connection between the first transmission line 410 and the third transmission line 450, and node X represents an electrical connection between the second transmission line 430 and the third transmission line 450. The nodes W, X, Y and Z may be implemented as any suitable electrical connections dependent on a selected physical implementation. As but one example, the nodes W, X, Y and Z may represent solder pads on a printed circuit board (PCB).

The first transmission line 410 generally includes a first pair of electrical conductors, which will be referred to as a first conductor 462 and a second conductor 464, both of which are wound around the solid magnetic core 426. The second transmission line 430 generally includes a second pair of electrical conductors, which will be referred to as a third conductor 466 and a fourth conductor 468, both of which are wound around the solid magnetic core 426. In a typical implementation, the first and second conductors 462 and 464 are wound around the common core 426 in a direction (or sense) opposite to that of the third and fourth conductors 466 and 468. The third transmission line 450 generally includes a third pair of electrical conductors, which will be referred to as a fifth conductor 472 and a sixth conductor 474. Generally, no limitation is placed on the configuration of the transmission lines 410, 430 and 450 or their respective conductor pairs. The type of transmission line utilized depends on the specific application of the illustrated transmission line transformer 400, some example including coaxial cables, twisted-pair wires, twin-leads, strip lines, and microstrips. FIG. 4 provides one example of a way of utilizing coaxial cables. Thus in FIG. 4, the center conductors (or cores) of coaxial cables are designated by the letter “c” and the outer conductors (or shields) of coaxial cables are designated by the letter “s.” In the specific example, the first conductor 462 is the center conductor and the second conductor 464 is the shield of a coaxial cable utilized as the first transmission line 410; the third conductor 466 is the center conductor and the fourth conductor 468 is the shield of a coaxial cable utilized as the second transmission line 430; and the fifth conductor 472 is the center conductor and the sixth conductor 474 is the shield of a coaxial cable utilized as the third transmission line 450.

In certain preferred implementations of the three transmission lines 410, 430 and 450, their respective physical lengths should be equal to each other so that their output phases will match. As used herein, the term “equal” encompasses ranges such as “substantially equal,” “about equal,” “approximately equal,” and the like, so as to account for manufacturing tolerances, measurement inaccuracy, or any other source or cause of imprecision or inaccuracy that may occur in practical implementations.

To implement the 1:9 transformation utilizing only the single, common core 426, the first transmission line 410, second transmission line 430 and third transmission line 450 are interfaced as follows. Node Y of the input port 412 is in signal communication with the first conductor 462 of T1, the fourth conductor 468 of T2, and the sixth conductor 474 of T3. Node Z of the input port 412 is in signal communication with the second conductor 464 of T1, the third conductor 466 of T2, and the fifth conductor 472 of T3. Node U of the output port 414 is in signal communication with the first conductor 462 of T1 (on the output side of the winding). Node V of the output port 414 is in signal communication with the third conductor 466 of T2 (on the output side of the winding). Node W is in signal communication with the second conductor 464 of T1 (on the output side of the winding) and the sixth conductor 474 of T3. Node X is in signal communication with the fourth conductor 468 of T2 (on the output side of the winding) and the fifth conductor 472 of T3.

In the implementation specifically illustrated in FIG. 4, the transformation of 1:9 has been considered in the direction of the input port 412 to the output port 414. That is, if the input port 412 has an impedance of Z, the output port 414 will have an impedance of 9Z. It will be noted, however, that the circuit illustrated in FIG. 4 may be operated in reverse and thus utilized as a 9:1 transformer, in which case an input impedance of Z will be transformed to an output impedance of (1/9)Z. Accordingly, for convenience the term “1:9 transformer” as used in the present disclosure also encompasses the term “9:1 transformer,” unless specified otherwise. It thus can be seen that the first port 412 may be implemented as an output port while the second port 414 may be implemented as an input port.

In FIG. 4, the single-core transformer 400 may be assumed to be balanced, in which case the input source and the output load are both balanced with respect to ground. It will be noted, however, that the single-core transformer 400 may alternatively be utilized as a balun, i.e., for balanced-to-unbalanced transformation. As readily appreciated by persons skilled in the art, in the case of a balun, either the input port 412 or the output port 414 is balanced with respect to ground while the other port 414 or 412 operates with one of its terminals (or nodes) grounded.

In practice, the single-core transformer 400 illustrated in FIG. 4 may be implemented in several alternative ways. Various examples of physical configurations for the transmission lines 410, 430 and 450 have been noted above. At high power levels, the use of coaxial cables may be preferred while at low power levels twisted-pair wire or twin-lead wire may be more appropriate. On the other hand, alternative implementations may employ coaxial cable at low power levels, especially at high frequencies, or employ twisted-pair or twin-lead wire at high powers. Stripline or microstrip configurations may also be utilized as previously noted. Such configurations may be flexible so as to be wound onto a core, or printed on a PCB with the core clamping around the stripline or microstrip through-holes in the PCB. The solid magnetic core 426 may be toroidal, binocular (multi-aperture) or have any other suitable form, a few additional examples being rods, pot-cores, beads, E-cores, I-cores, E-I cores, or the like. With some types of cores such as beads or clamp-on cores, the single-core transformer 400 may be constructed by threading or clamping one or more cores (functioning as a single core) onto the transmission lines 410 and 430. Such a configuration may have advantages in applications where the transmission lines 410 and 430 are rigid or where it is beneficial to have a significant linear physical separation between the input port 412 and output port 414 of the single-core transformer 400.

The single-core transformer 400 illustrated in FIG. 4 may provide several advantages when utilized in various implementations. In comparison to previous 1:9 transmission line transformers such as illustrated in FIG. 3, the single-core transformer 400 requires only one core 426. Moreover, the size of the core 426 and physical length of the transmission lines 410, 430 and 450 can be made smaller in this single-core transformer 400. The single-core transformer 400 thus takes up a smaller physical volume and footprint, i.e., is more compact than previously known designs. Additionally, component cost is reduced due to the reduced number of cores required and, in some implementations, because a smaller core 426 may be utilized. Because the physical lengths of the transmission lines 410, 430 and 450 can be made shorter, efficiency is improved (e.g., less signal loss through the circuit). The single-core transformer 400 also provides a wide bandwidth, particularly on the low-frequency side.

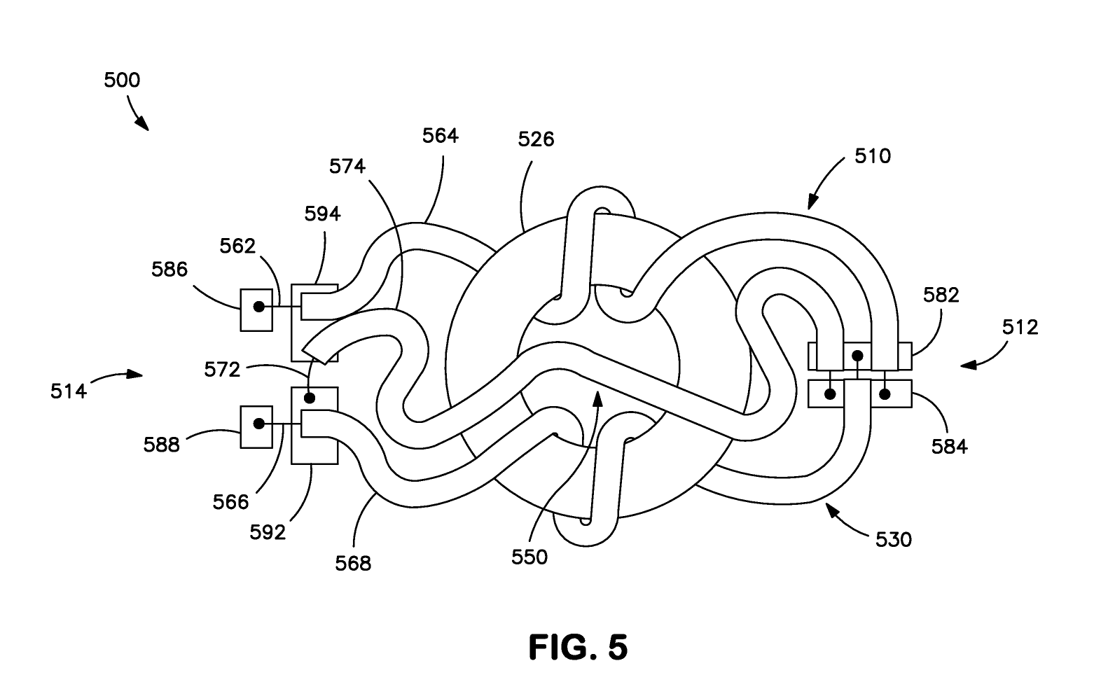

FIG. 5 is a top plan view of one example of a physical implementation of a single-core 1:9 transmission line transformer 500 in accordance with the present teachings. The example of FIG. 5 is consistent with the schematic circuit of FIG. 4, and the correlations among like components should be readily apparent. In FIG. 5, the single-core transformer 500 includes a first transmission line 510, a second transmission line 530, and a third transmission line 550, all of which are provided in the form of semi-rigid coaxial cables in the present example. The first transmission line 510 includes a center conductor 562 and an outer shield 564, the second transmission line 530 includes a center conductor 566 and an outer shield 568, and the third transmission line 550 includes a center conductor 572 and an outer shield 574. For illustrative purposes, the center conductors 562, 566 and 572 are shown extending out from the corresponding outer shields 564, 568 and 574 to facilitate showing electrical connections, but such extensions in practice are not necessarily required. For instance, electrical connection with the end of an outer shield may be made through a hole formed through the outermost insulating layer of a coaxial cable. In the present example, the first transmission line 510 and the second transmission line 530 are both wound in opposite directions around a toroidal core 526. While in this example, the respective windings of the first transmission line 510 and the second transmission line 530 each consist of two turns, it will be understood that the number of turns utilized in any particular application will depend on various factors such as, for example, the frequency range to be spanned, the circuit impedance, the properties of the core, etc. The third transmission line 550 is not wound around the core 526 and, in effect, may be considered as having a gas (e.g., air) core. All three coaxial cables should have the same physical length (when straightened out from end to end) for optimum performance. To realize this condition, depending on the locations of the electrical connections to the three transmission lines 510, 530 and 550, the third transmission line 550 may be bent or curved one or more times such as in a serpentine fashion.

The single-core transformer 500 includes an input port 512 and an output port 514. In the present example, the input port 512 is formed by a first solder pad 582 and a second solder pad 584 and the output port 514 is formed by a third solder pad 586 and a fourth solder pad 588. By way of example, the solder pads 582, 584, 586 and 588 may be part of or formed on a PCB (not shown) to which the single-core transformer 500 is anchored. In comparison to the circuit illustrated in FIG. 4, the first solder pad 582 corresponds to the node (or terminal, etc.) Y, the second solder pad 584 corresponds to the node Z, the third solder pad 586 corresponds to the node U, and the fourth solder pad 588 corresponds to the node V. The single-core transformer 500 includes a fifth solder pad 592 corresponding to the node X and a sixth solder pad 594 corresponding to the node W. The first solder pad 582 is connected to the respective input ends of the shield 564 of the first transmission line 510, the center conductor 566 of the second transmission line 530, and the shield 574 of the third transmission line 550. The second solder pad 584 is connected to the respective input ends of the center conductor 562 of the first transmission line 510, the shield 568 of the second transmission line 530, and the center conductor 572 of the third transmission line 550. The third solder pad 586 is connected to the output end of the center conductor 562 of the first transmission line 510. The fourth solder pad 588 is connected to the output end of the center conductor 566 of the second transmission line 530. The fifth solder pad 592 is connected to the respective output ends of the shield 568 of the second transmission line 530 and the center conductor 572 of the third transmission line 550. The sixth solder pad 594 is connected to the respective output ends of the shield 564 of the first transmission line 510 and the shield 574 of the third transmission line 550.

As in the more general case of the circuit illustrated in FIG. 4, the single-core transformer 500 illustrated in FIG. 5 may be operated as a 9:1 transformer (in which case the foregoing “inputs” are “outputs” and vice versa), and may be configured for balun, unbal, balbal, or unun operation. Moreover, the practical example illustrated in FIG. 5 may provide one or more of the advantages noted above for the more general case shown in FIG. 4.

In general, terms such as “communicate” and “in . . . communication with” (for example, a first component “communicates with” or “is in communication with” a second component) are used herein to indicate a structural, functional, mechanical, electrical, signal, optical, magnetic, electromagnetic, ionic or fluidic relationship between two or more components or elements. As such, the fact that one component is said to communicate with a second component is not intended to exclude the possibility that additional components may be present between, and/or operatively associated or engaged with, the first and second components.

It will be understood that various aspects or details of the invention may be changed without departing from the scope of the invention. Furthermore, the foregoing description is for the purpose of illustration only, and not for the purpose of limitation—the invention being defined by the claims.

What is claimed is:

1. A single-core transmission line transformer comprising:
a first transmission line wound around a solid core of magnetic material;
a second transmission line wound around the solid core;
a first port interconnecting respective first ends of the first transmission line and the second transmission line in parallel;
a second port communicating with respective second ends of the first transmission line and the second transmission line; and
a third transmission line communicating with the first transmission line and the second transmission line without being wound around any solid core, the third transmission line comprising a first side communicating with the respective first ends of the first transmission line and the second transmission line, and a second side communicating with the respective second ends of the first transmission line and the second transmission line,
wherein the impedance transformation ratio of the single-core transmission line transformer is 1:9 in a direction from the first port to the second port.

2. The single-core transmission line transformer of claim 1, wherein the first transmission line has a first physical length, the second transmission line has a second physical length equal to the first physical length, and the third transmission line has a third physical length equal to the first physical length.

3. The single-core transmission line transformer of claim 1, wherein the first transmission line and the second transmission line are wound around the solid core in opposite directions.

4. The single-core transmission line transformer of claim 1, wherein the first port is an input port and the second port is an output port, and the impedance transformation ratio is 1:9 in a direction from the input port to the output port.

5. The single-core transmission line transformer of claim 1, wherein the first port is an output port and the second port is an input port, and the impedance transformation ratio is 1:9 in a direction from the output port to the input port.

6. The single-core transmission line transformer of claim 1, wherein:
the first transmission line comprises a first conductor and a second conductor wound around the solid core, the second transmission line comprises a third conductor and a fourth conductor wound around the solid core, and the third transmission line comprises a fifth conductor and a sixth conductor;
the first port comprises a first node communicating with the first conductor and the fourth conductor in parallel at the respective first ends of the first transmission line and the second transmission line, and communicating with the sixth conductor;
the first port comprises a second node communicating with the second conductor and the third conductor in parallel at the respective first ends of the first transmission line and the second transmission line, and communicating with the fifth conductor;
the second port comprises a third node communicating with the first conductor at the second end of the first transmission line, and a fourth node communicating with the third conductor at the second end of the second transmission line; and
the fifth conductor communicates with the fourth conductor at the second end of the second transmission line; and
the sixth conductor communicates with the second conductor at the second end of the first transmission line.

7. The single-core transmission line transformer of claim 6, wherein the first conductor, the third conductor and the fifth conductor are respective coaxial cable inner conductors, and the second conductor, the fourth conductor and the sixth conductor are respective coaxial cable outer conductors.

8. The single-core transmission line transformer of claim 6, wherein the first node, the second node, the third node and the fourth node are respective electrical connections formed on a circuit board.

9. The single-core transmission line transformer of claim 8, wherein the fifth conductor communicates with the fourth conductor via a fifth node and the sixth conductor communicates with the second conductor via a sixth node, the fifth node and the sixth node being formed as respective electrical connections on the circuit board.

10. The single-core transmission line transformer of claim 1, wherein the first transmission line, the second transmission line and the third transmission line comprise structures selected from the group consisting of coaxial cables, twisted-pair wires, twin-lead cables, strip lines and microstrips.

11. A method for forming a single-core transmission line transformer, the method comprising:
winding a first transmission line around a solid core of magnetic material;
winding a second transmission line around the solid core;
forming a first port by interconnecting respective first ends of the first transmission line and the second transmission line in parallel;
forming a second port by placing respective second ends of the first transmission line and the second transmission line in communication with respective nodes of the second port; and
placing a third transmission line in communication with the first transmission line and the second transmission line without being wound around any solid core, the third transmission line comprising a first side communicating with the respective first ends of the first transmission line and the second transmission line, and a second side communicating with the respective second ends of the first transmission line and the second transmission line,
wherein the impedance transformation ratio of the single-core transmission line transformer is 1:9 in a direction from the first port to the second port.

12. The method of claim 11, wherein the first transmission line has a first physical length, the second transmission line has a second physical length equal to the first physical length, and the third transmission line has a third physical length equal to the first physical length.

13. The method of claim 11, wherein the first transmission line and the second transmission line are wound around the solid core in opposite directions.

14. The method of claim 11, further comprising connecting the first port to a circuit as an input port and connecting the second port to the circuit as an output port, wherein the impedance transformation ratio is 1:9 in a direction from the input port to the output port.

15. The method of claim 11, wherein connecting the first port to a circuit as an output port and connecting the second port to the circuit as an input port, wherein the impedance transformation ratio is 1:9 in a direction from the output port to the input port.

16. The method of claim 11, wherein:
winding the first transmission line comprises winding a first conductor and a second conductor of the first transmission line around the solid core;
winding the second transmission line comprises winding a third conductor and a fourth conductor of the second transmission line around the solid core;
the third transmission line comprises a fifth conductor and a sixth conductor;
forming the first port comprises placing a first node of the first port in communication with the first conductor and the fourth conductor in parallel at the respective first ends of the first transmission line and the second transmission line, and in communication with the sixth conductor;
forming the first port further comprises placing a second node of the first port in communication with the second conductor and the third conductor in parallel at the respective first ends of the first transmission line and the second transmission line, and in communication with the fifth conductor;
the nodes of the second port comprise a third node and a fourth node, and forming the second port comprises placing the third node in communication with the first conductor at the second side of the first transmission line, and placing the fourth node in communication with the third conductor at the second side of the second transmission line;
the fifth conductor is placed in communication with the fourth conductor at the second side of the second transmission line; and
the sixth conductor is placed in communication with the second conductor at the second side of the first transmission line.

17. The method of claim 16, wherein the first conductor, the third conductor and the fifth conductor are respective coaxial cable inner conductors, and the second conductor, the fourth conductor and the sixth conductor are respective coaxial cable outer conductors.

18. The method of claim 16, further comprising forming the first node, the second node, the third node and the fourth node as respective electrical connections on a circuit board.

19. The method of claim 18, further comprising placing the fifth conductor communicates with the fourth conductor via a fifth node and the sixth conductor communicates with the second conductor via a sixth node, the fifth node and the sixth node being formed as respective electrical connections on the circuit board.

20. The method of claim 11, wherein the first transmission line, the second transmission line and the third transmission line comprise structures selected from the group consisting of coaxial cables, twisted-pair wires, twin-lead cables, strip lines and microstrips.
